(19) United States
(12) Patent Application Publication
(10) Pub. No.: US 2025/0309068 A1
(43) Pub. Date: Oct. 2, 2025

(54) SEMICONDUCTOR DEVICE

(71) Applicant: Rohm Co., Ltd., Kyoto-shi, Kyoto (JP)

(72) Inventor: Hiroaki MATSUBARA, Kyoto-shi (JP)

(21) Appl. No.: 19/237,837

(22) Filed: Jun. 13, 2025

Related U.S. Application Data
(63) Continuation of application No. PCT/JP2023/043583, filed on Dec. 6, 2023.

(30) Foreign Application Priority Data
Dec. 21, 2022 (JP) 2022-204281

(51) Int. Cl. H01L 23/495; H01L 23/00; H01L 23/31; H01L 25/065

(52) U.S. Cl. CPC H01L 23/49544; H01L 23/3121; H01L 23/49575; H01L 25/0655; H01L 24/32; H01L 24/48; H01L 24/73; H01L 2224/32245; H01L 2224/48245; H01L 2224/73265

(57) ABSTRACT

The semiconductor device includes a first die pad, a second die pad, a first suspension lead, a second suspension lead and a sealing resin. The first and second suspension leads are spaced apart from two first side faces of the sealing resin and exposed to the outside from the second side face of the sealing resin. The first suspension lead includes a first inner portion covered by the sealing resin and a first outer portion connected to the first inner portion. As viewed in a third direction, the first inner portion includes a first portion extending from a boundary defined by the extension line of a first edge of the first die pad to the first die pad. The cross-sectional area of the first portion in its extension direction is larger than that of the first outer portion in its extension direction.

### TECHNICAL FIELD

The present disclosure relates to semiconductor devices.

### BACKGROUND ART

The semiconductor device disclosed in JP-A-2016-207714 comprises two die pads, a control element (controller), and a drive element (gate driver). The control element and the drive element are individually mounted on the two die pads, respectively. The semiconductor device drives switching elements such as IGBTs and MOSFETs. The semiconductor device is used, for example, in an inverter circuit.

In the above semiconductor device, the power voltage supplied to the drive element is greater than the voltage applied to the switching element, and the power voltage supplied to the control element is different from the power voltage supplied to the drive element. Thus, the voltage applied to the control element and its conductive path is different from the voltage applied to the drive element and its conductive path. In the semiconductor device, an insulating element is interposed in the electrical signal transmission path between the control element and the drive element. This insulates the control element and its conductive path from the drive element and its conductive path. This prevents the control element and the drive element from being electrically broken down.

The above semiconductor device comprises two suspension leads connected to the die pad on which the control element and the insulating element are mounted, a plurality of intermediate leads connected to the control element, and a sealing resin. The sealing resin covers the two die pads, the control element, the drive element, and the insulating element. The two suspension leads, together with the plurality of intermediate leads, are exposed to the outside from the same side of the sealing resin. During the manufacturing process of the semiconductor device, the die pad connected to the two suspension leads is subjected to loads, such as those from a bonding tool. As a result, bending forces act on each suspension lead, causing each suspension lead to deflect in the direction of the load. If the deflection of each suspension lead is large, the tilt of the die pad connected to the suspension leads will become large. This may reduce the bonding strength between the control/insulating elements and the die pad, or cause poor bonding of the wires connected to these elements.

### BRIEF DESCRIPTION OF DRAWINGS

FIG. 1 is a plan view of a semiconductor device according to a first embodiment of the present disclosure.

FIG. 2 is a plan view corresponding to FIG. 1, with the sealing resin being transparent.

FIG. 3 is a front view of the semiconductor device shown in FIG. 1.

FIG. 4 is a left side view of the semiconductor device shown in FIG. 1.

FIG. 5 is a right side view of the semiconductor device shown in FIG. 1.

FIG. 6 is a cross-sectional view along VI-VI line in FIG. 2.

FIG. 7 is a cross-sectional view along VII-VII line in FIG. 2.

FIG. 8 is a cross-sectional view along VIII-VIII line in FIG. 2.

FIG. 9 is a partially enlarged view of FIG. 2.

FIG. 10A is a cross-sectional view along XA-XA line in FIG. 9.

FIG. 10B is a cross-sectional view along XB-XB line in FIG. 9.

FIG. 10C is a cross-sectional view along XC-XC line in FIG. 9.

FIG. 11A is a cross-sectional view of the second inner portion of the second suspension lead in the direction in which it extends.

FIG. 11B is a cross-sectional view of the second outer portion of the second suspension lead in the direction in which it extends.

FIG. 12A is a cross-sectional view of the third inner portion of the third suspension lead in the direction in which it extends.

FIG. 12B is a cross-sectional view of the third outer portion of the third suspension lead in the direction in which it extends.

FIG. 13 is a plan view of the semiconductor device according to a second embodiment of the present disclosure.

FIG. 14 is a plan view corresponding to FIG. 13, with the sealing resin being transparent.

FIG. 15 is a rear view of the semiconductor device shown in FIG. 13.

FIG. 16 is a left side view of the semiconductor device shown in FIG. 13.

FIG. 17 is a plan view of the lead frame for manufacturing the semiconductor device shown in FIG. 13.

FIG. 18 is a partially enlarged view of FIG. 14.

FIG. 19A is a cross-sectional view along XIXA-XIXA line in FIG. 18.

FIG. 19B is a cross-sectional view along XIXB-XIXB line in FIG. 18.

FIG. 19C is a cross-sectional view along XIXC-XIXC in FIG. 18.

FIG. 20 is a plan view of a semiconductor device according to a third embodiment of the present disclosure.

FIG. 21 is a plan view corresponding to FIG. 20, with the sealing resin being transparent.

FIG. 22 is a left side view of the semiconductor device shown in FIG. 20.

FIG. 23 is a right side view of the semiconductor device shown in FIG. 20.

FIG. 24 is an enlarged view of a portion of FIG. 21.

FIG. 25A is a cross-sectional view along XXVA-XXVA line FIG. 24.

FIG. 25B is a cross-sectional view along XXVB-XXVB line in FIG. 24.

FIG. 25C is a cross-sectional view along XXVC-XXVC line in FIG. 24.

### DETAILED DESCRIPTION OF EMBODIMENTS

Embodiments in accordance with the present disclosure will be explained below with reference to the accompanying drawings.

### First Embodiment

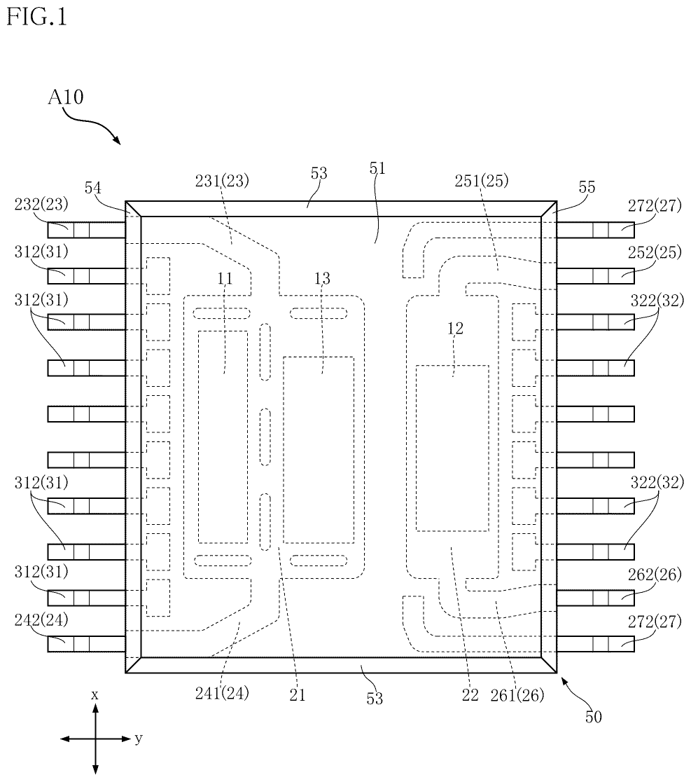

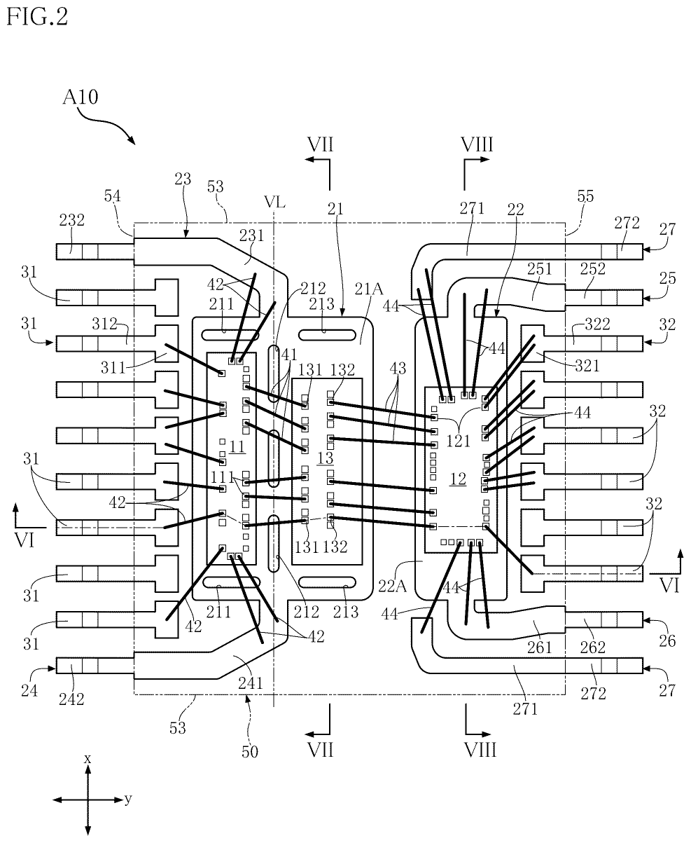

Referring to FIGS. 1 to 12B, a semiconductor device A10 according to a first embodiment of the present disclosure will be described. The semiconductor device A10 comprises a first semiconductor element 11, a second semiconductor element 12, an insulating element 13, a first die pad 21, a second die pad 22, a first suspension lead 23, a second suspension lead 24, a third suspension lead 25, a fourth suspension lead 26, a plurality of first intermediate leads 31, a plurality of second intermediate leads 32, and a sealing resin 50. Furthermore, the semiconductor device A10 comprises two outer leads 27, a plurality of first wires 41, a plurality of second wires 42, a plurality of third wires 43, and a plurality of fourth wires 44. The semiconductor device A10 may be surface-mounted on a wiring board of an inverter device for an electric vehicle or a hybrid vehicle, for example. The packaging type of the semiconductor device A10 is a small outline package (SOP). However, the packaging type of the semiconductor device A10 is not limited to SOP. For ease of understanding, FIG. 2 shows the sealing resin 50 as transparent and its outer shape is indicated by imaginary lines (two-dot chain lines).

In the description of the semiconductor device A10, one direction perpendicular to the normal direction of the first mounting surface 21A of the first die pad 21 to be described below is referred to as the “first direction x.” One direction perpendicular to the first direction x is called the “second direction y.” The direction perpendicular to both the first direction x and the second direction y is called the “third direction z.” The third direction z corresponds to the normal direction of the first mounting surface 21A.

In the semiconductor device A10, the first semiconductor element 11, the second semiconductor element 12, and the insulating element 13 are individual elements. The second semiconductor element 12 is opposite from the first semiconductor element 11 with respect to the insulating element 13 in the second direction y. The insulating element 13 is located adjacent to the first semiconductor element 11 in the first direction x. As viewed in the third direction z, the first semiconductor element 11, the second semiconductor element 12, and the insulating element 13 have their respective rectangular shapes with long sides extending in the first direction x.

The first semiconductor element 11 controls the second semiconductor element 12. The first semiconductor element 11 includes a circuit for converting electrical signals inputted from other semiconductor devices into PWM control signals, a transmitting circuit for transmitting the PWM control signals to the second semiconductor element 12, and a receiving circuit for receiving electrical signals from the second semiconductor element 12.

The second semiconductor element 12 drives a switching element(s) located outside the semiconductor device A10. Such a switching element is, for example, an IGBT (Insulated Gate Bipolar Transistor) or a MOSFET (Metal-Oxide-Semiconductor Field-Effect Transistor). The second semiconductor element 12 includes a receiving circuit for receiving a PWM control signal, a circuit for driving the switching elements based on the PWM control signal, and a transmitting circuit for transmitting an electrical signal to the first semiconductor element 11. The electrical signal is, for example, a signal outputted from a temperature sensor located near a motor.

The insulating element 13 is configured to cause electrical signals such as PWM (Pulse Width Modulation) control signals to be transmitted in an insulated state. The insulating element 13 may be of an inductive coupling type. An example of such an insulating element 13 is an insulated transformer. An insulated transformer transmits electrical signals in an insulated state by using inductively coupled two inductors (coils). The two inductors may be a transmitter-side inductor and a receiver-side inductor. These two inductors may be stacked along the third direction z. Between the transmitter-side inductor and the receiver-side inductor, a dielectric layer composed of silicon dioxide (SiO₂) or the like is provided. This dielectric layer electrically insulates the transmitter-side inductor from the receiver-side inductor. Alternatively, the insulating element 13 may be of a capacitive type. An example of the capacitive type insulating element 13 is a capacitor.

The respective voltages applied to the first semiconductor element 11 and the second semiconductor element 12 are different from each other. Thus, a potential difference may occur between the first semiconductor element 11 and the second semiconductor element 12. In the semiconductor device A10, the voltage applied to the second semiconductor element 12 is higher than the voltage applied to the first semiconductor element 11. Further, the power voltage supplied to the second semiconductor element 12 is higher than the power voltage supplied to the first semiconductor element 11.

The semiconductor device A10 comprises a first circuit including the first semiconductor element 11 and a second circuit including the second semiconductor element 12, and these two circuits are insulated from each other by the insulating element 13. The insulating element 13 is electrically connected to the first circuit and the second circuit. The first circuit includes, in addition to the first semiconductor element 11, the first suspension lead 23, the second suspension lead 24, and a plurality of first intermediate leads 31. The second circuit includes the second die pad 22, a third suspension lead 25, a fourth suspension lead 26, and a plurality of second intermediate leads 32. The first circuit and the second circuit are held at different potentials. In the semiconductor device A10, the potential of the first circuit is higher than that of the second circuit. The insulating element 13 relays signals between the first circuit and the second circuit. For example, in an inverter device of an electric vehicle or a hybrid vehicle, the voltage applied to the ground (GND) of the first semiconductor element 11 is approximately 0 V, while the voltage applied to the ground of the second semiconductor element 12 may transiently exceed 600 V.

As shown in FIGS. 2 and 6, the first semiconductor element 11 has a plurality of first electrodes 111. The plurality of first electrodes 111 are provided on the upper surface of the first semiconductor element 11 (the surface facing the same side as the first mounting surface 21A of the first die pad 21 described later). The plurality of first electrodes 111 may be made of a material such as aluminum (Al). The plurality of first electrodes 111 are electrically connected to the circuit formed in the first semiconductor element 11.

As shown in FIGS. 2 and 6, the second semiconductor element 12 has a plurality of second electrodes 121. The plurality of second electrodes 121 are provided on the upper surface of the second semiconductor element 12 (the surface facing the same side as the second mounting surface 22A of the second die pad 22 described later). The plurality of second electrodes 121 may be made of a material such as aluminum. The plurality of second electrodes 121 are electrically connected to the circuit formed in the second semiconductor element 12.

As shown in FIGS. 2 and 6, the insulating element 13 is located between the second semiconductor element 12 and the first semiconductor element 11 in the third direction z. The first semiconductor element 11 is opposite from the second semiconductor element 12 with respect to the insulating element 13 in the second direction y. A plurality of third electrodes 131 and a plurality of fourth electrodes 132 are provided on the upper surface of the insulating element 13 (the surface facing the same side as the first mounting surface 21A of the first die pad 21 described later). The third electrodes 131 and the fourth electrodes 132 are electrically connected to either the transmitter-side inductor or the receiver-side inductor. The third electrodes 131 are arranged along the first direction x and are positioned between the first semiconductor element 11 and the second semiconductor element 12 in the second direction y. The fourth electrodes 132 are arranged along the first direction x and positioned opposite from the first semiconductor element 11 with respect to the third electrodes 131 in the second direction y. The third electrodes 131 and the fourth electrodes 132 may be made of a material such as aluminum.

As shown in FIG. 1, the sealing resin 50 covers the first semiconductor element 11, the second semiconductor element 12, the insulating element 13, the first die pad 21, and the second die pad 22. As shown in FIG. 6, the sealing resin 50 further covers the first wires 41, the second wires 42, the third wires 43, and the fourth wires 44. The sealing resin 50 is made of an insulating material. For instance, the sealing resin 50 may be made of a material including an epoxy resin. As viewed in the third direction z, the sealing resin 50 is rectangular.

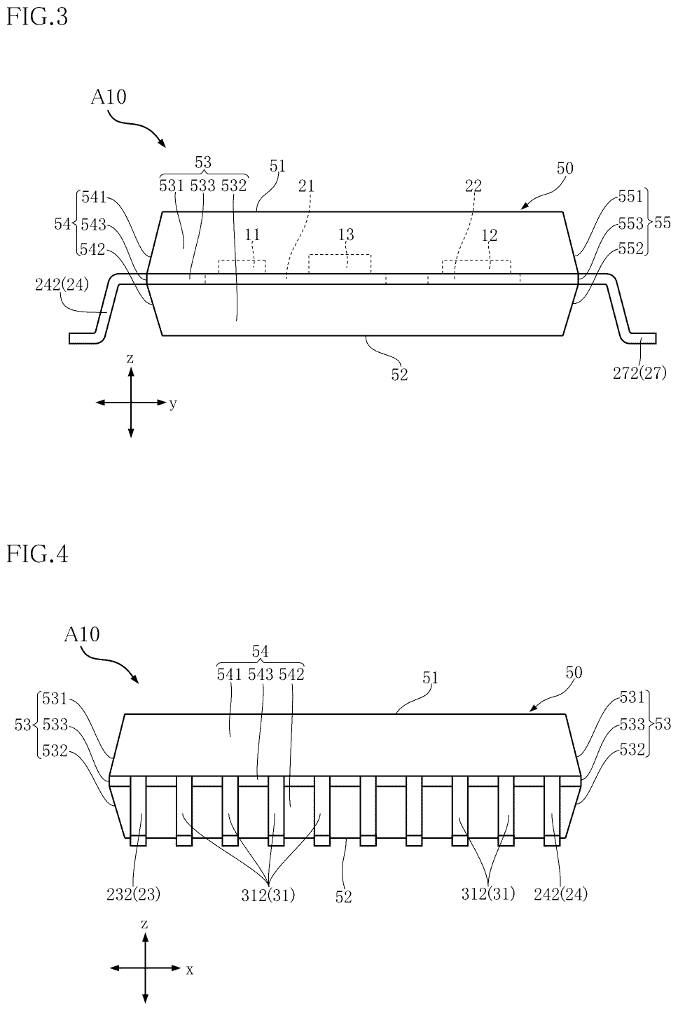

As shown in FIGS. 3 to 5, the sealing resin 50 has a top face 51, a bottom face 52, two first side faces 53, a second side face 54 and a third side face 55.

As shown in FIGS. 3 to 5, the top face 51 and the bottom face 52 are arranged to face away from each other in the third direction z. The top face 51 and the bottom face 52 are flat (or substantially flat).

As shown in FIGS. 3 to 5, the two first side faces 53 are connected to the top face 51 and the bottom face 52, and face away from each other in the first direction x. Each first side 53 includes a first upper portion 531, a first lower portion 532, and a first intermediate portion 533. The first upper portion 531 is connected to the top face 51 at one end in the third direction z and to the first intermediate portion 533 at the other end in the third direction z. The first upper portion 531 is inclined with respect to the top face 51. The first lower part 532 is connected to the bottom face 52 at one end in the third direction z and to the first intermediate part 533 at the other end in the third direction z. The first lower part 532 is inclined with respect to the bottom face 52. The first intermediate part 533 is located between the first upper part 531 and the first lower part 532 in the third direction z. The first intermediate portion 533 contains the third direction z as an in-plane direction. As viewed in the third direction z, the first intermediate portion 533 is located outwardly of the top face 51 and the bottom face 52.

As shown in FIGS. 3 and 4, the second side face 54 connects to the top face 51 and the bottom face 52 and faces one side in the second direction y. The second side face 54 is located closer to the first die pad 21 than the third side 55. The second side face 54 includes a second upper portion 541, a second lower portion 542 and a second intermediate portion 543. The second upper portion 541 is connected to the top face 51 at one end in the third direction z and to the second intermediate portion 543 at the other end in the third direction z. The second upper portion 541 is inclined with respect to the top face 51. The second lower portion 542 has one end in the third direction z connected to the bottom face 52 and the other end in the third direction z connected to the second intermediate portion 543. The second lower portion 542 is inclined with respect to the bottom face 52. The second intermediate portion 543 is located between the second upper portion 541 and the second lower portion 542 in the third direction z. The second intermediate portion 543 contains the third direction z as an in-plane direction. As viewed in the third direction z, the second intermediate portion 543 is located outwardly of the top face 51 and the bottom face 52.

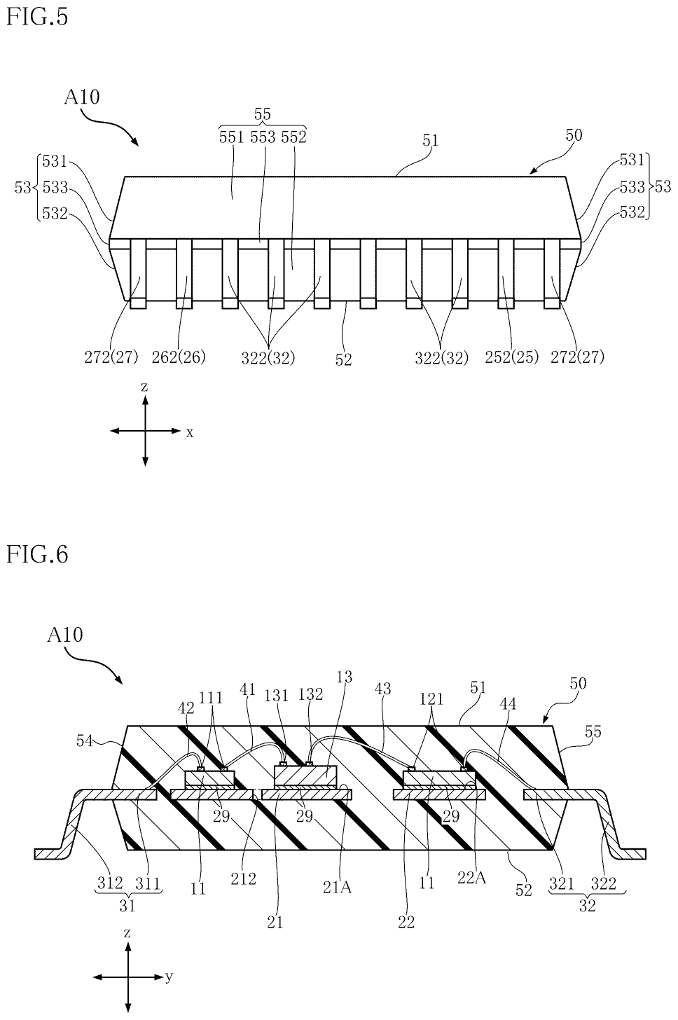

As shown in FIGS. 3 and 5, the third side face 55 connects to the top face 51 and the bottom face 52 and faces away from the second side 54 in the second direction y. The third side face 55 is located closer to the second die pad 22 than the second side face 54. The third side face 55 includes a third upper portion 551, a third lower portion 552, and a third intermediate portion 553. The third upper portion 551 is connected to the top face 51 at one end in the third direction z and to the third intermediate portion 553 at the other end in the third direction z. The third upper portion 551 is inclined with respect to the top face 51. The third lower portion 552 has one end in the third direction z connected to the bottom face 52 and the other end in the third direction z connected to the third intermediate portion 553. The third lower portion 552 is inclined with respect to the bottom face 52. The third intermediate portion 553 is located between the third upper portion 551 and the third lower portion 552 in the third direction z. The third intermediate portion 553 contains the third direction z as an in-plane direction. As viewed in the third direction z, the third intermediate portion 553 is located outwardly of the top face 51 and the bottom face 52.

The first die pad 21, the second die pad 22, the first suspension lead 23, the second suspension lead 24, the third suspension lead 25, the fourth suspension lead 26, the two outer leads 27, the first intermediate leads 31, and the second intermediate leads 32 are made of a material such as copper (Cu).

The first die pad 21 and the second die pad 22 are spaced apart from each other in the second direction y, as shown in FIGS. 1 and 2. In the semiconductor device A10, the first semiconductor element 11 and the insulating element 13 are mounted on the first die pad 21 and the second semiconductor element 12 is mounted on the second die pad 22. As viewed in the third direction z, the area of the first die pad 21 is larger than the area of the second die pad 22. Alternatively, the first semiconductor element 11 may be mounted on the first die pad 21, while the second semiconductor element 12 and the insulating element 13 may be mounted on the second die pad 22.

As shown in FIGS. 6 and 7, the first die pad 21 has a first mounting surface 21A facing one side of the third direction z. The first semiconductor element 11 and the insulating element 13 are bonded to the first mounting surface 21A via a bonding layer 29. The bonding layer 29 comprises a paste containing metal particles. The metal particles are, for example, silver (Ag). Thus, the bonding layer 29 is an electrical conductor. Alternatively, the bonding layer 29 may be solder. The first die pad 21 is covered by the sealing resin 50.

As shown in FIG. 2, FIG. 6 and FIG. 7, the first die pad 21 is formed with two first holes 211, a plurality of second holes 212, and two third holes 213. The two first holes 211, the second holes 212, and the two third holes 213 each penetrate through the first die pad 21 in the third direction z. The two first holes 211 are located on the respective sides of the first semiconductor element 11 in the first direction x. Each of the two first holes 211 extends in the second direction y. The second holes 212 are located between the first semiconductor element 11 and the insulating element 13 in the second direction y. Each of the second holes 212 extends in the first direction x. The second holes 212 are arranged along the first direction x. The two third holes 213 are located on the respective sides of the insulating element 13 in the first direction x. Each of the two third holes 213 extends in the second direction y.

The first suspension lead 23 is connected to one side of the first die pad 21 in the first direction x, as shown in FIGS. 1 and 2. The first suspension lead 23 is spaced apart from the two first side faces 53 of the sealing resin 50. The first suspension lead 23 is exposed to the outside from the second side face 54 of the sealing resin 50. The first suspension lead 23 includes a first inner portion 231 and a first outer portion 232. The first inner portion 231 is connected to the first die pad 21 and is covered by the sealing resin 50. The first outer portion 232 is connected to the first inner portion 231 and is exposed to the outside. As viewed in the third direction z, the first outer portion 232 extends in the second direction y. The first outer portion 232 is bent in a gull-wing shape as viewed in the first direction x. The surface of the first outer portion 232 is plated with, for example, tin.

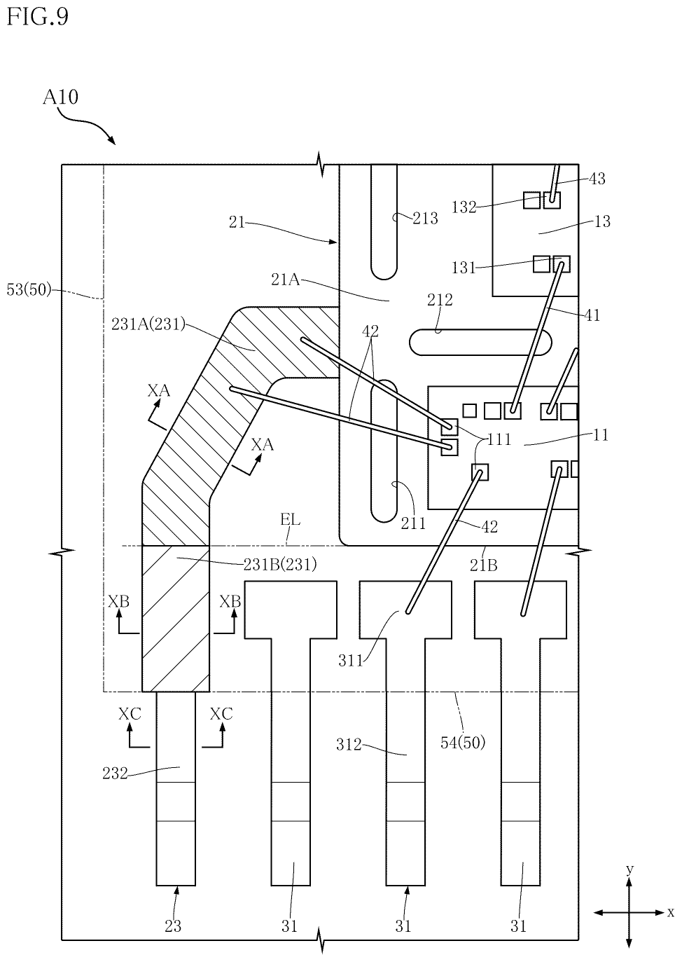

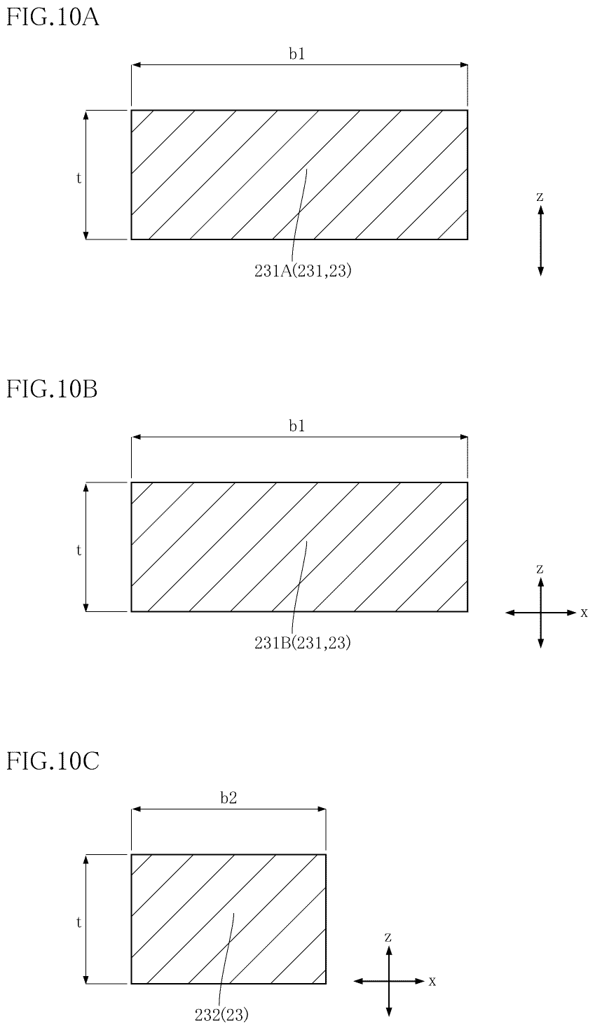

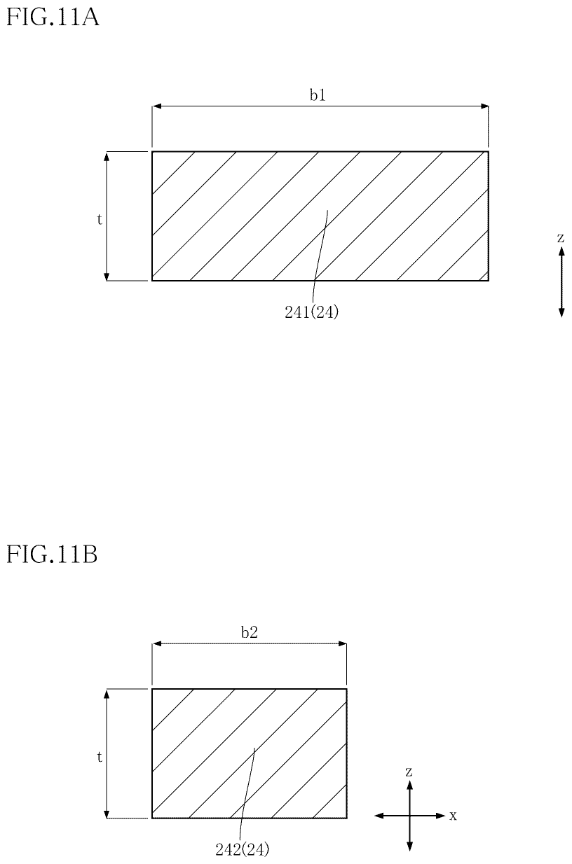

As shown in FIG. 9, the first die pad 21 has a first edge 21B extending in the first direction x, and this first edge 21B is closest to the second side face 54 of the sealing resin 50 compared to the other edges. As viewed in the third direction z, the first inner portion 231 includes a first portion 231A, which extends from the boundary defined by the extension line EL of the first edge 21B to the first die pad 21. The first portion 231A is spaced apart from the second side face 54. In FIG. 9, oblique lines are drawn correspondingly to the first portion 231A. As shown in FIGS. 10A and 10C, the cross-sectional area of the first portion 231A in its extension direction is larger than the cross-sectional area in the extension direction of the first outer portion 232. It should be noted that the “cross-sectional area in the extension direction” refers to the area in the cross-section perpendicular to the direction in which the object in question extends.

As shown in FIG. 9, the first inner portion 231 includes a second portion 231B that connects the first portion 231A and the first outer portion 232. In FIG. 9, the portion corresponding to the second portion 231B is shown by oblique lines. As shown in FIGS. 10B and 10C, the cross-sectional area of the second portion 231B in its extension direction is larger than the cross-sectional area of the first outer portion 232 in its extension direction.

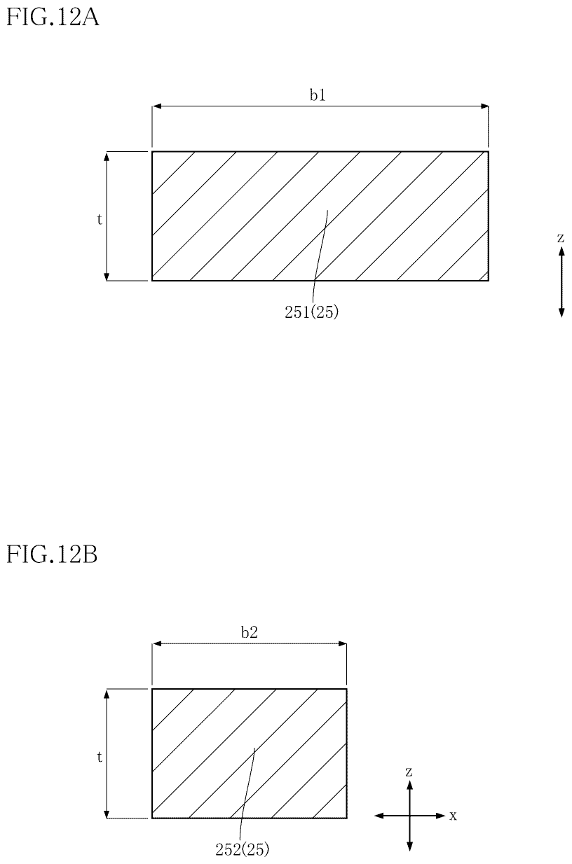

The second suspension lead 24 is opposite from the first suspension lead 23 with respect to the first die pad 21, as shown in FIGS. 1 and 2, and the lead 24 is connected to the first die pad 21. The second suspension lead 24 is spaced apart from the two first side faces 53 of the sealing resin 50. The second suspension lead 24 is exposed to the outside from the second side face 54 of the sealing resin 50. The second suspension lead 24 has a second inner portion 241 and a second outer portion 242. The second inner portion 241 is connected to the first die pad 21 and is covered by the sealing resin 50. The second outer portion 242 is connected to the second inner portion 241 and is exposed to the outside. As viewed in the third direction z, the second outer portion 242 extends in the second direction y. As shown in FIG. 3, the second outer portion 242 is bent in a gull wing shape as viewed in the first direction x. The surface of the second outer portion 242 is plated with, for example, tin. As shown in FIGS. 11A and 11B, like the first suspension lead 23, the cross-sectional area of the second inner portion 241 in its extension direction is larger than the cross-sectional area of the second outer portion 242 in its extension direction.

As shown in FIG. 7, as viewed in the first direction x, the first inner portion 231 of the first suspension lead 23 and the second inner portion 241 of the second suspension lead 24 overlap with the first die pad 21. As shown in FIG. 2, as viewed in the third direction z, the first inner portion 231, the second inner portion 241, and the second holes 212 in the first die pad 21 overlap with the virtual line VL extending along the first direction x.

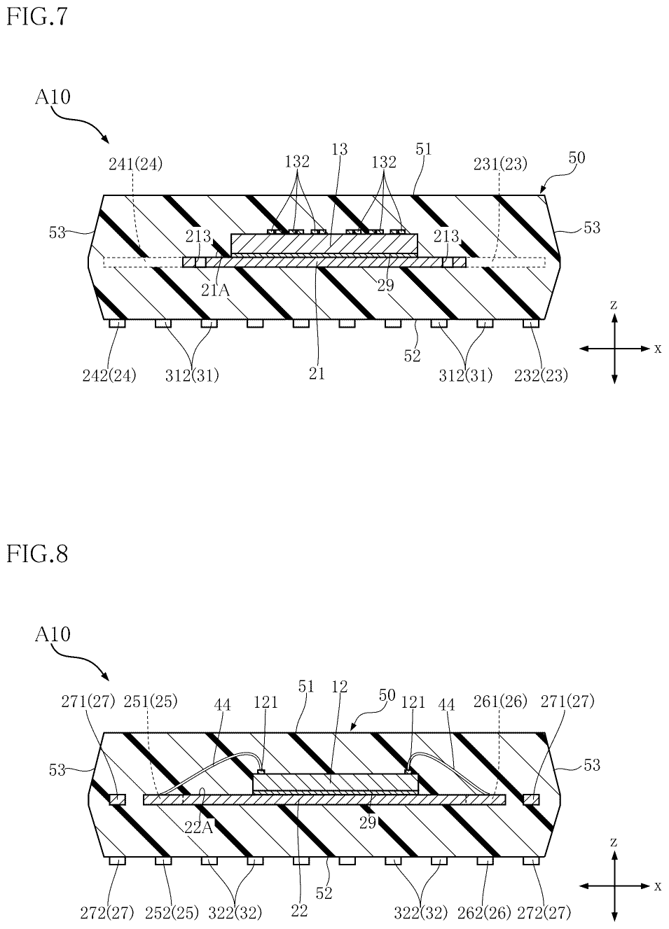

As shown in FIGS. 6 and 8, the second die pad 22 has a second mounting surface 22A facing the same side as the first mounting surface 21A of the first die pad 21 in the third direction z. The second semiconductor element 12 is bonded to the second mounting surface 22A via a bonding layer 29. The second die pad 22 is covered with the sealing resin 50.

As shown in FIGS. 1 and 2, the third suspension lead 25 is located on the same side as the first suspension lead 23 with respect to the first die pad 21 and the lead 25 is connected to the second die pad 22. The third suspension lead 25 is spaced apart from the two first side faces 53 of the sealing resin 50. The third suspension lead 25 is exposed to the outside from the third side face 55 of the sealing resin 50. The third suspension lead 25 has a third inner portion 251 and a third outer portion 252. The third inner portion 251 is connected to the second die pad 22 and is covered by the sealing resin 50. The third outer portion 252 is connected to the third inner portion 251 and is exposed to the outside. As viewed in the third direction z, the third outer portion 252 extends in the second direction y. The third outer portion 252 is bent in a gull-wing shape as viewed in the first direction x. The surface of the third outer portion 252 is plated with, for example, tin. As shown in FIGS. 12A and 12B, like the first suspension lead 23, the cross-sectional area in the extension direction of the third inner portion 251 is larger than the cross-sectional area in the extension direction of the third outer portion 252.

As shown in FIGS. 1 and 2, the fourth suspension lead 26 is opposite from the third suspension lead 25 with respect to the second die pad 22 and the lead 26 is connected to the second die pad 22. The fourth suspension lead 26 is spaced apart from the two first side faces 53 of the sealing resin 50. The fourth suspension lead 26 is exposed to the outside from the third side face 55 of the sealing resin 50. The fourth suspension lead 26 has a fourth inner portion 261 and a fourth outer portion 262. The fourth inner portion 261 is connected to the second die pad 22 and is covered by the sealing resin 50. The fourth outer portion 262 is connected to the fourth inner portion 261 and is exposed to the outside. As viewed in the third direction z, the fourth outer portion 262 extends in the second direction y. The fourth outer portion 262 is bent in a gull-wing shape as viewed in the first direction x. The surface of the fourth outer portion 262 is plated with, for example, tin. Like the first suspension lead 23, the cross-sectional area of the fourth inner portion 261 in its extension direction is larger than the cross-sectional area of the fourth outer portion 262 in its extension direction.

The two outer leads 27 sandwich the third suspension lead 25 and the fourth suspension lead 26 in the first direction x, as shown in FIGS. 1 and 2. Each of the two outer leads 27 is spaced apart from the second die pad 22 and the two first side faces 53 of the sealing resin 50. Each of the two outer leads 27 is exposed to the outside from the third side face 55 of the sealing resin 50. Each of the two outer leads 27 is electrically connected to the second semiconductor element 12 via one of the fourth wires 44.

As shown in FIG. 2, each of the two outer leads 27 has an inner portion 271 and an outer portion 272. The inner portion 271 is covered with the sealing resin 50. The outer portion 272 is connected to the inner portion 271 and is exposed to the outside. As viewed in the third direction z, the outer portion 272 extends in the second direction y. As shown in FIG. 3, the outer portion 272 is bent in a gull wing shape as viewed in the first direction x. The surface of the outer portion 272 is plated with tin, for example.

As shown in FIG. 8, as viewed in the first direction x, the third inner portion 251 of the third suspension lead 25, the fourth inner portion 261 of the fourth suspension lead 26, and the inner portions 271 of the outer leads 27 overlap with the second die pad 22.

The first intermediate leads 31 are located between the first suspension lead 23 and the second suspension lead 24 in the first direction x, as shown in FIGS. 1 and 2. The first intermediate leads 31 are opposite from the second die pad 22 with respect to the first die pad 21 in the second direction y. The first intermediate leads 31 are arranged along the first direction x. At least one of the first intermediate leads 31 is electrically connected to the first semiconductor element 11 via one of the second wires 42.

As shown in FIGS. 2 and 6, each first intermediate lead 31 has an inner portion 311 and an outer portion 312. The inner portion 311 is covered with the sealing resin 50. The outer portion 312 is connected to the inner portion 311 and is exposed to the outside from the second side face 54 of the sealing resin 50. As viewed in the third direction z, the outer portion 312 extends in the second direction y. As viewed in the first direction x, the outer portion 312 is bent in a gull wing shape. The shape of the outer portion 312 is the same as that of the second outer portion 242 of the second suspension lead 24 shown in FIG. 3. The surface of the outer portion 312 is plated with tin, for example.

The second intermediate leads 32 are located between the third suspension lead 25 and the fourth suspension lead 26 in the first direction x, as shown in FIGS. 1 and 2. The second intermediate leads 32 are opposite from the first die pad 21 with respect to the second die pad 22 in the second direction y. The second intermediate leads 32 are arranged along the first direction x. At least one of the second intermediate leads 32 is electrically connected to the second semiconductor element 12 via one of the fourth wires 44.

As shown in FIGS. 2 and 6, each second intermediate lead 32 has an inner portion 321 and an outer portion 322. The inner portion 321 is covered by the sealing resin 50. The outer portion 322 is connected to the inner portion 321 and is exposed to the outside from the third side face 55 of the sealing resin 50. As viewed in the third direction z, the outer portion 322 extends in the second direction y. As viewed in the first direction x, the outer portion 322 is bent in a gull wing shape. The shape of the outer portion 322 is the same as that of the outer portion 272 of the outer lead 27 shown in FIG. 3. The surface of the outer portion 322 is plated with, for example, tin.

Each of first wires 41 is electrically connected to one of the third electrodes 131 of the insulating element 13 and one of the first electrodes 111 of the first semiconductor element 11, as shown in FIGS. 2 and 6. Thus, the first semiconductor element 11 is electrically connected to the insulating element 13. The first wires 41 are arranged along the first direction x. At least one of the first wires 41 extends over one of the second holes 212 provided in the first die pad 21. The first wires 41 may be made of gold, for example.

As shown in FIGS. 2 and 6, each of the second wires 42 is electrically connected to one of the first electrodes 111 of the first semiconductor element 11 and to the inner portion 311 of one of the first intermediate leads 31. Thus, at least one of the first intermediate leads 31 is electrically connected to the first semiconductor element 11. At least one of the second wires 42 is electrically connected to one of the first electrodes 111 and to the first inner portion 231 of the first suspension lead 23. Thus, the first suspension lead 23 is electrically connected to the first semiconductor element 11. Further, At least one of the second wires 42 is electrically connected to one of the first electrodes 111 and to the second inner portion 241 of the second suspension lead 24. Thus, the second suspension lead 24 is electrically connected to the first semiconductor element 11. At least either of the first suspension lead 23 and the second suspension lead 24 serves as the ground of the first semiconductor element 11. The second wires 42 may be made of gold, for example. Alternatively, each second wire 42 may include a core member made of copper and a coating member made of palladium for covering the core member.

Each of the third wires 43 is electrically connected to one of the fourth electrodes 132 of the insulating element 13 and to one of the second electrodes 121 of the second semiconductor element 12, as shown in FIGS. 2 and 6. Thus, the second semiconductor element 12 is electrically connected to the insulating element 13. The third wires 43 are arranged along the first direction x. The third wires 43 bridge between the first die pad 21 and the second die pad 22. The third wires 43 may be made of gold, for example.

Each of the fourth wires 44 is electrically connected to one of the second electrodes 121 of the second semiconductor element 12 and to the inner portion 321 of one of the second intermediate leads 32, as shown in FIGS. 2 and 6. Thus, at least one of the second intermediate leads 32 is electrically connected to the second semiconductor element 12. At least one of the fourth wires 44 is electrically connected to one of the second electrodes 121 and to the third inner portion 251 of the third suspension lead 25. Thus, the third suspension lead 25 is electrically connected to the second semiconductor element 12. At least one of the fourth wires 44 is electrically connected to one of the second electrodes 121 and to the fourth inner portion 261 of the fourth suspension lead 26. Thus, the fourth suspension lead 26 is electrically connected to the second semiconductor element 12. At least either of the third suspension lead 25 and the fourth suspension lead 26 serves as the ground of the second semiconductor element 12. At least one of the fourth wires 44 is electrically connected to one of the second electrodes 121 and to the inner portion 271 of one of the two outer leads 27. Thus, at least either of the two outer leads 27 is electrically connected to the second semiconductor element 12. The fourth wires 44 may be made of gold, for example. Alternatively, each fourth wire 44 may include a core member made of copper and a coating member made of palladium for covering the core member.

Generally, in a motor driver circuit of an inverter device, a half-bridge circuit is configured to include a low-side (low-potential side) switching element(s) and a high-side (high-potential side) switching element(s). Hereinbelow, these switching elements are assumed to be MOSFETs. In the low-side switching element, the reference potentials for the source of the switching element and the gate driver to drive the switching element are a ground potential. On the other hand, in the high-side switching element, the reference potentials for the source of the switching element and the gate driver to drive the switching element correspond to the potential at the output node of the half-bridge circuit. As the potential at the output node varies in response to the operations of the high-side and the low-side switching elements, the reference potential of the gate driver for driving the high-side switching element also varies. When the high-side switching element is on, the reference potential is equal to to the voltage applied to the drain of the high-side switching element (e.g., 600 V or higher). In the semiconductor device A10, the ground of first semiconductor element 11 and the ground of second semiconductor element 12 are separated. Thus, when the semiconductor device A10 is used as a gate driver for driving a high-side switching element, a voltage equal to the voltage applied to the drain of the high-side switching element is transiently applied to the ground of the second semiconductor element 12.

As described below, the semiconductor device A10 may have, without limitation, the following advantages.

As described above, the semiconductor device A10 comprises the first die pad 21, the first suspension lead 23, the second suspension lead 24, the first semiconductor element 11, and the sealing resin 50. The first suspension lead 23 has the first inner portion 231 covered by the sealing resin 50 and the first outer portion 232 connected to the first inner portion 231 and exposed to the outside. As viewed in the third direction z, the first inner portion 231 includes the first portion 231A extending from the boundary defined by the extension line EL of the first edge 21B of the first die pad 21 to the first die pad 21. The cross-sectional area of the first portion 231A in its extension direction is larger than the cross-sectional area of the first outer portion 232 in its extension direction. With this configuration, the bending rigidity at the cross section of the first inner portion 231 is greater than the bending rigidity at the cross section of the first outer portion 232. Thus, when a load in the third direction z acts on the first die pad 21 from a bonding tool or the like, the deflection of the first suspension lead 23 in the third direction z is reduced more than is conventionally possible. Therefore, according to the above configuration, it is possible to stabilize the position or posture of the die pad of the semiconductor device A10 during manufacture.

The first inner portion 231 of the first suspension lead 23 includes the second portion 231B that connects the first portion 231A and the first outer portion 232. The cross-sectional area of the second portion 231B in its extension direction is larger than the cross-sectional area of the first outer portion 232 in its extension direction. With this configuration, the bending rigidity at the cross section of the first inner portion 231 can be more greater than the bending rigidity at the cross section of the first outer portion 232. Thus, when a load in the third direction z acts on the first die pad 21, the deflection of the first suspension lead 23 in the third direction z can be further reduced.

The second suspension lead 24 has the second inner portion 241 covered with the sealing resin 50 and the second outer portion 242 connected to the second inner portion 241 and exposed to the outside. The cross-sectional area of the second inner portion 241 in its extension direction is larger than the cross-sectional area of the second outer portion 242 in its extension direction. with this configuration, the bending rigidity at the cross section of the second inner portion 241 can be greater than the bending rigidity at the cross section of the second outer portion 242. Thus, when a load in the third direction z acts on the first die pad 21, the deflection of the second suspension lead 24 in the third direction z is reduced more than is conventionally possible. Thus, the position or posture of the first die pad 21 can be more stable.

The semiconductor device A10 further comprises the insulating element 13 mounted on the first die pad 21. The first die pad 21 is formed with two first holes 211 and a plurality of second holes 212, each of which penetrates through the die pad 21 in the third direction z. The two first holes 211 are located on both sides in the first direction x of the first semiconductor element 11. The second holes 212 are disposed between the first semiconductor element 11 and the insulating element 13 in the second direction y. With this configuration, in forming the sealing resin 50 for the manufacture of the semiconductor device A10, the fluidized sealing resin 50 passes through the first holes 211 and the second holes 212, thereby preventing insufficient filling of the sealing resin 50, thereby suppressing the occurrence of voids in the sealing resin 50.

As viewed in the third direction z, the first inner portion 231 of the first suspension lead 23, the second inner portion 241 of the second suspension lead 24, and the second holes 212 in the first die pad 21 are arranged to overlap with the virtual line VL extending in the first direction x. With this configuration, in forming the sealing resin 50 for the manufacture of the semiconductor device A10, the first die pad 21 can be prevented from rotating around the first direction x by the fluidized sealing resin 50 coming into contact with the first die pad 21. Thus, the coating thickness of the sealing resin 50 on the first die pad 21 can be made uniform. Further, since the second holes 212 are aligned along the first direction x, it is possible to effectively suppress the undesired rotation of the first die pad 21 around the first direction x.

As viewing in the first direction x, the first inner portion 231 of the first lead 23 and the second inner portion 241 of the second lead 24 are arranged to overlap with the first die pad 21. With this configuration, it is possible to make the semiconductor device A10 advantageously small in size in the third direction z.

### Second Embodiment

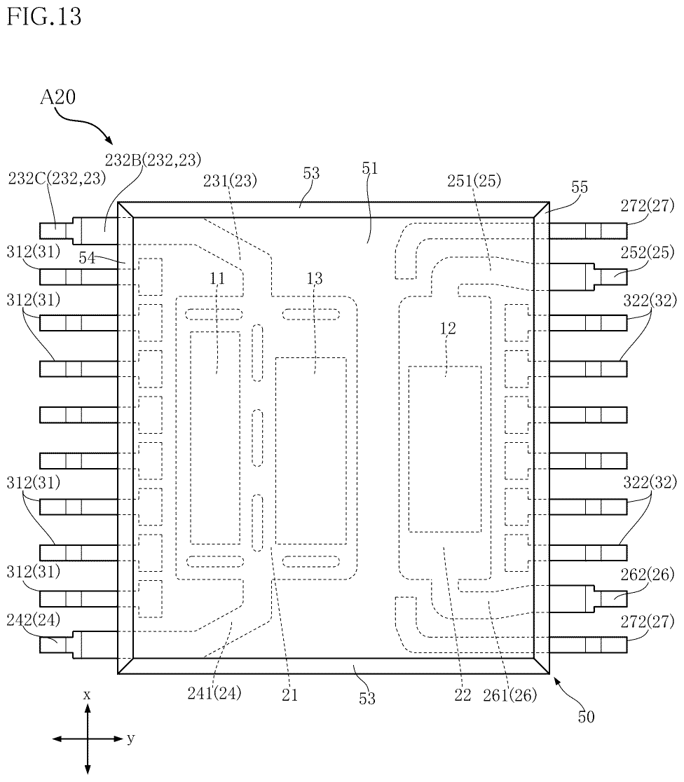

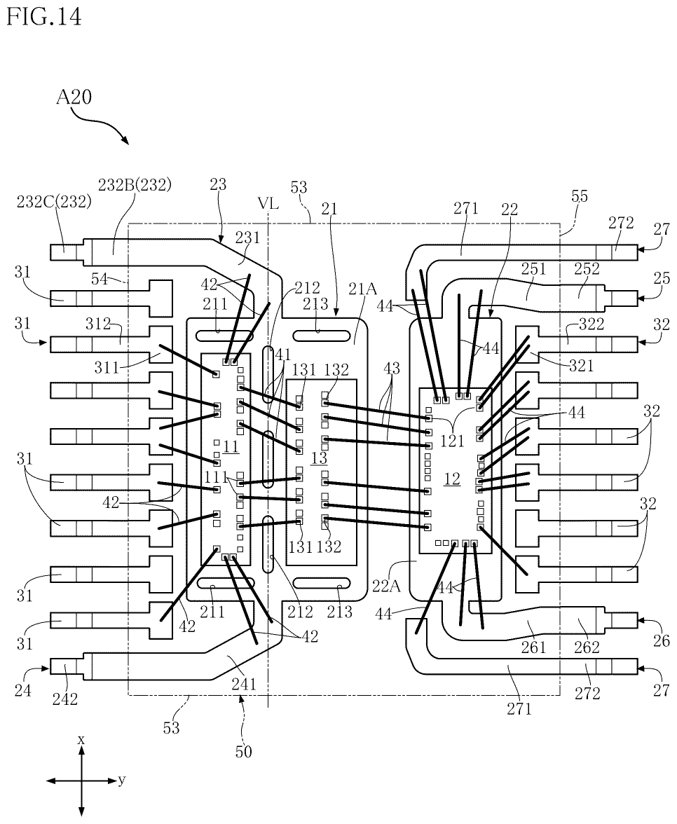

Referring to FIGS. 13 to 19C, a semiconductor device A20 according to a second embodiment of the present disclosure will be described. In these figures, the same reference numerals are used for the same or similar elements as those described above with the semiconductor device A10, and redundant descriptions may be omitted. For ease of understanding, the sealing resin 50 is depicted as being transparent in FIG. 14, and its outer shape is shown by imaginary lines.

The semiconductor device A20 is different from the semiconductor device A10 in configurations relating to the first suspension lead 23, the second suspension lead 24, the third suspension lead 25, and the fourth suspension lead 26.

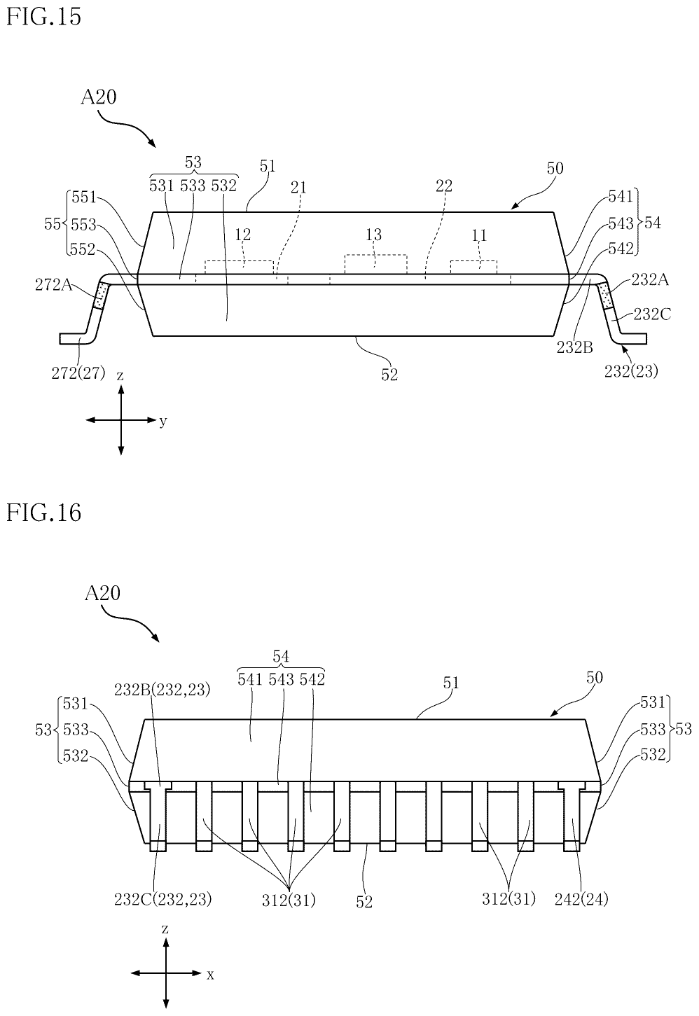

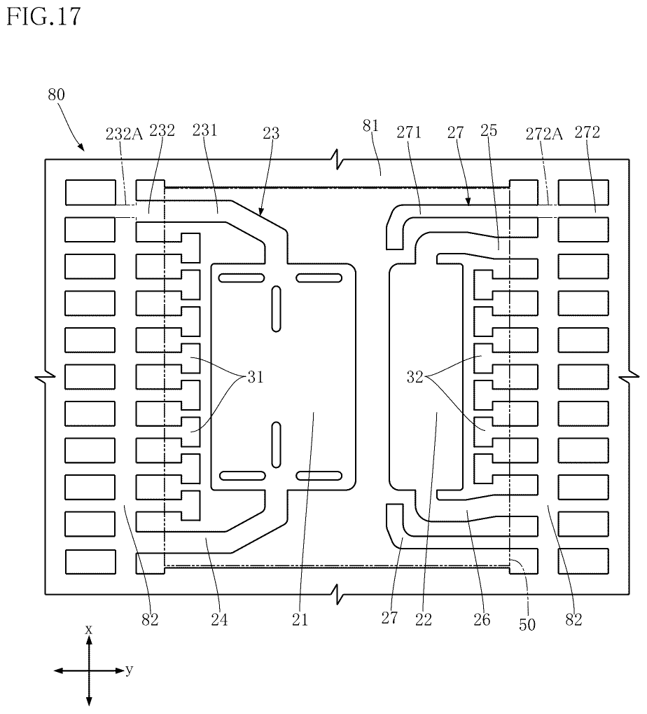

As seen from FIG. 15, two cutting marks 232A facing away from each other in the first direction x are formed on the first outer portion 232 of the first suspension lead 23. These cutting marks 232A are a trace formed on the first outer portion 232 by making cuts in the relevant tie bar 82 shown in FIG. 17.

As shown in FIG. 17, in manufacturing the semiconductor device A20, the first suspension lead 23 is obtained from the lead frame 80 together with the first die pad 21 and the second die pad 22. The lead frame 80 includes a frame portion 81 and two tie bars 82. The frame portion 81 surrounds the first die pad 21 and the second die pad 22. The first die pad 21, the second die pad 22, the first suspension lead 23, the second suspension lead 24, the third suspension lead 25, the fourth suspension lead 26, the two outer leads 27, the first intermediate leads 31, and the second intermediate leads 32 are connected to the frame portion 81. The two tie bars 82 are spaced apart from each other in the second direction y. Each tie bar 82 is connected to the frame portion 81 at two positions spaced apart in the first direction x. The first suspension lead 23, the second suspension lead 24, and the first intermediate leads 31 are connected to one of the two tie bars 82, while the third suspension lead 25, the fourth suspension lead 26, the two outer leads 27, and the second intermediate leads 32 are connected to the other tie bar 82.

In manufacturing the semiconductor device A20, required cuts are made in the respective tie bars 82 after the sealing resin 50 is formed. As a result, cutting marks 232A are formed on the first outer portion 232 of the first suspension lead 23. Further, the first outer portion 232 is formed into a gull wing shape.

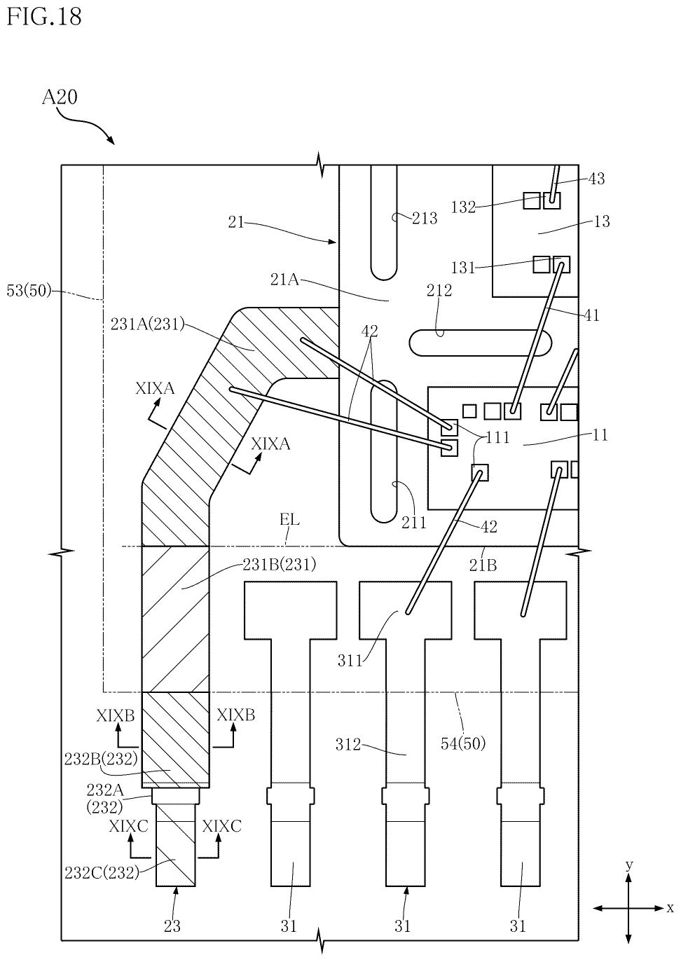

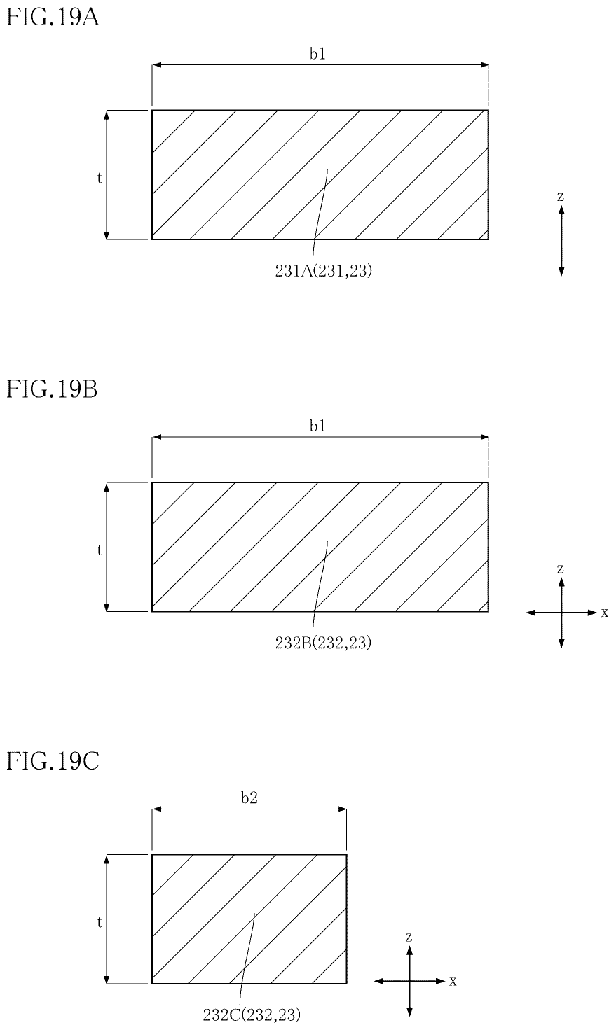

As shown in FIGS. 13, 14 and 16, the first outer portion 232 of the first suspension lead 23 includes a third portion 232B and a fourth portion 232C. As shown in FIG. 18, the third portion 232B is located between the second side face 54 of the sealing resin 50 and the cutting marks 232A. The fourth portion 232C is located opposite from the third portion 232B with respect to the cutting marks 232A. In FIG. 18, the third portion 232B and the fourth portion 232C are indicated by oblique lines. As shown in FIGS. 19B and 19C, the cross-sectional area of the third part 232B in its extension direction is larger than the cross-sectional area of the fourth part 232C in its extension direction.

As shown in FIGS. 18, 19A, 19B and 19C, in the semiconductor device A20, the cross-sectional area of the first portion 231A of the first inner portion 231 of the first suspension lead 23 in its extension direction is larger than any of the cross-sectional areas of the first outer portion 232 in its extension direction. The cross-sectional area of the third portion 232B of the first outer portion 232 of the first suspension lead 23 in its extension direction is equal to the cross-sectional area of the second portion 231B of the first inner portion 231 in its extension direction.

As shown in FIGS. 13 and 14, in the semiconductor device A20, the second outer portion 242 of the second suspension lead 24, the third outer portion 252 of the third suspension lead 25, and the fourth outer portion 262 of the fourth suspension lead 26 are each configured to have the same configurations as the first outer portion 232 of the first suspension lead 23 in terms of cutting marks (232A), the third portion (232B) and the fourth portion (232C).

As explained below, the semiconductor device A20 may have, without limitation, the following advantages.

The semiconductor device A20 includes the first die pad 21, the first suspension lead 23, the second suspension lead 24, the first semiconductor element 11, and the sealing resin 50. The first suspension lead 23 has the first inner portion 231 covered by the sealing resin 50 and the first outer portion 232 connected to the first inner portion 231 and exposed to the outside. As viewed in the third direction z, the first inner portion 231 includes the first portion 231A extending from the boundary defined by the extension line EL of the first edge 21B of the first die pad 21 to the first die pad 21. The cross-sectional area of the first portion 231A in its extension direction is larger than the cross-sectional area of the first outer portion 232 in its extension direction. With this configuration, it is possible to stabilize the position of the die pad in manufacturing the semiconductor device A20. Furthermore, As having configurations common to those of the semiconductor device A10, the semiconductor device A20 can enjoy the same advantages as the semiconductor device A10.

In the semiconductor device A20, the first outer portion 232 of the first suspension lead 23 includes the third portion 232B and the fourth portion 232C. The third portion 232B is located between the second side face 54 of the sealing resin 50 and the cutting marks 232A. The fourth portion 232C is opposite from the third portion 232B with respect to the cutting marks 232A. The cross-sectional area of the third portion 232B in its extension direction is larger than the cross-sectional area of the fourth portion 232C in its extension direction. With this configuration, the bending rigidity at the cross section of the first outer portion 232 is larger than that of the semiconductor device A10. Thus, when a load in the third direction z acts on the first die pad 21, the deflection of the first suspension lead 23 in the third direction z is further reduced compared to the case of the semiconductor device A10, thereby further stabilizing the position of the first die pad 21.

### Third Embodiment

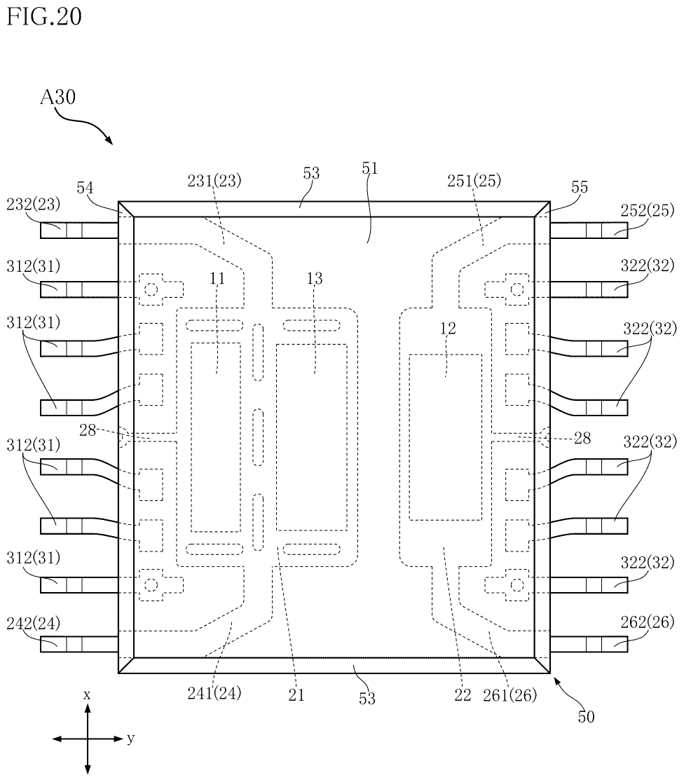

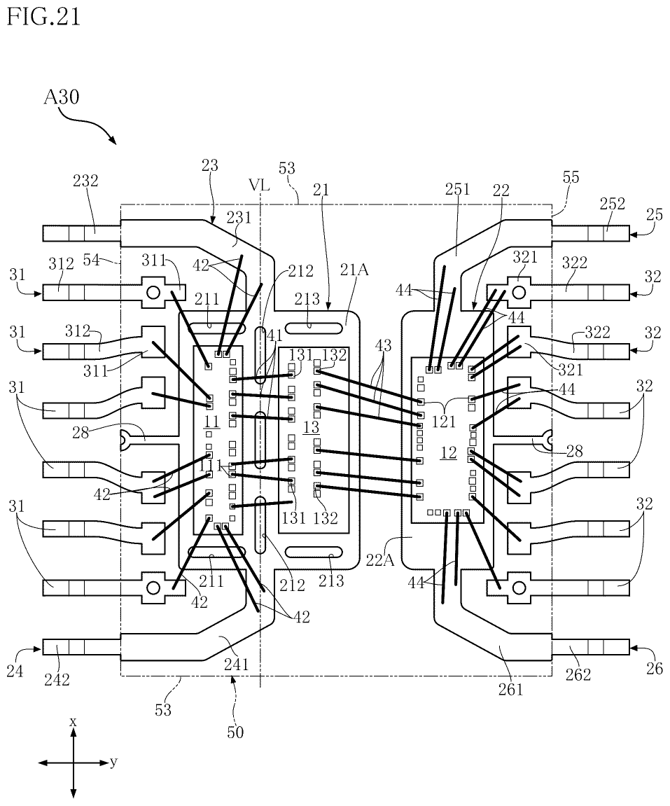

A semiconductor device A30 according to a third embodiment of the present disclosure is described below with reference to FIGS. 20 to 25C. In these figures, the same reference numerals are used for the same or similar elements as those described above with the semiconductor device A10, and redundant descriptions are omitted. For ease of understanding, the sealing resin 50 is depicted as being transparent in FIG. 21, and its outer shape is shown by imaginary lines.

The semiconductor device A30 is different from the semiconductor device A10 in that it has two support leads 28 instead of the two outer leads 27. Further, in the semiconductor device A30, the number of first intermediate leads 31 and the number of second intermediate leads 32 are smaller than in the semiconductor device A10.

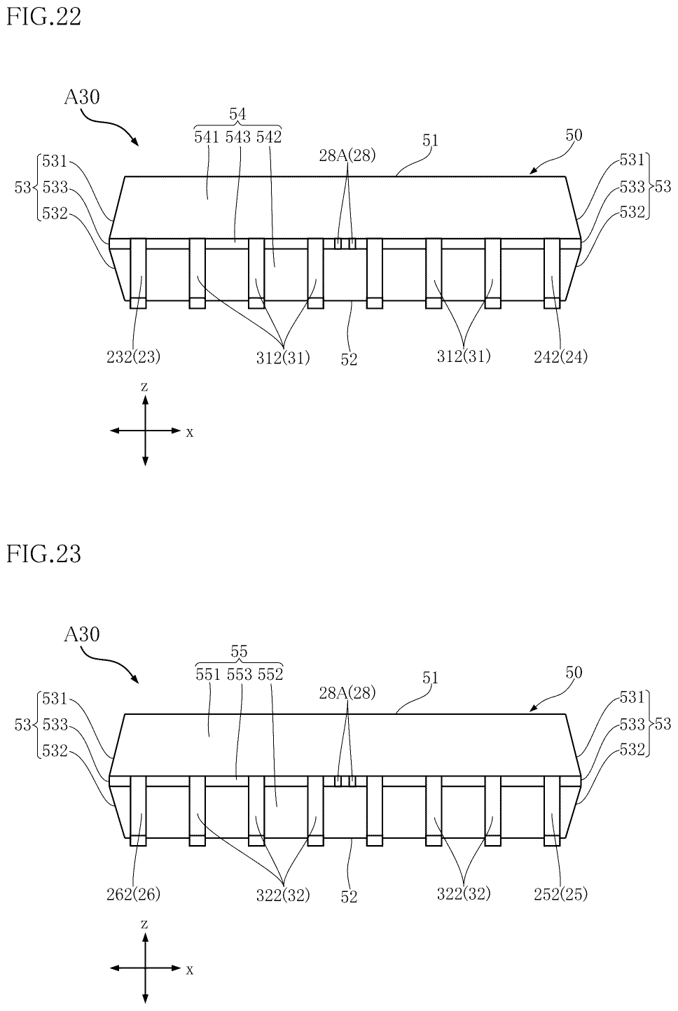

As shown in FIGS. 20 and 21, the two support leads 28 are spaced apart from each other in the second direction y. Each of the two support leads 28 extends in the second direction y. The two support leads 28 are connected to the first die pad 21 and the second die pad 22, respectively. As shown in FIGS. 22 and 23, each of the two support leads 28 has an end face 28A facing the second direction y. The end face 28A of the support lead 28 connected to the first die pad 21 is exposed from the second side face 54 of the sealing resin 50. The end face 28A of the support lead 28 connected to the second die pad 22 is exposed from the third side face 55 of the sealing resin 50.

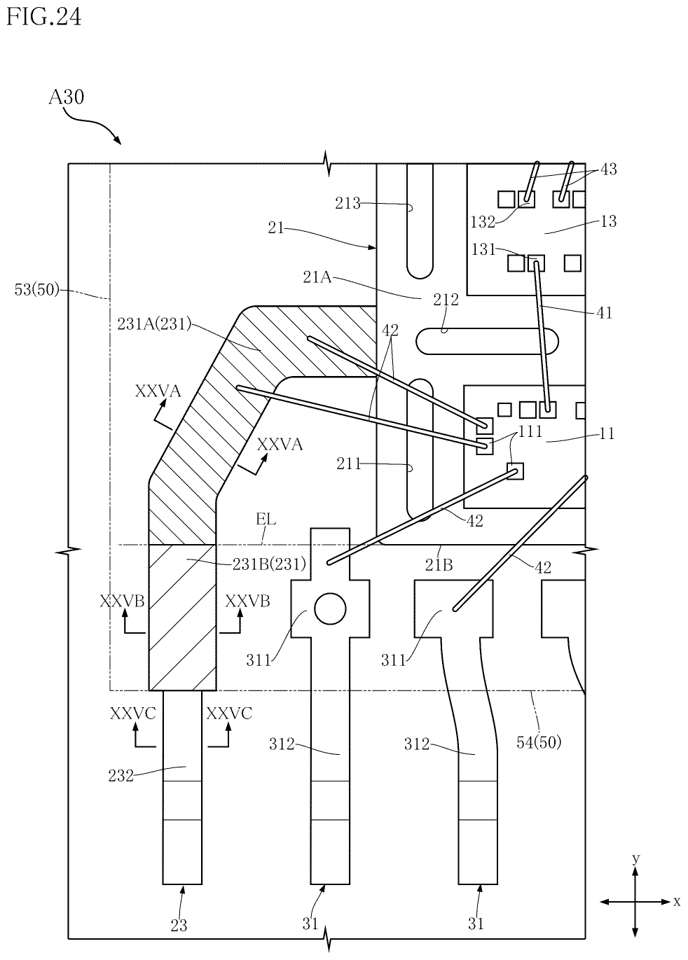

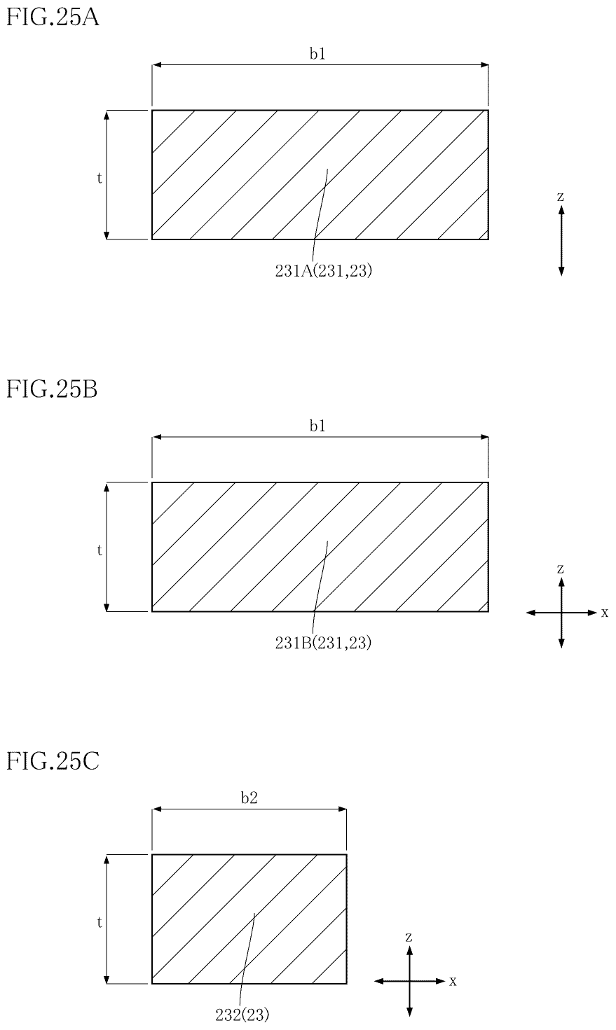

As shown in FIGS. 24, 25A and 25C, the first suspension lead 23 of the semiconductor device A30 is configured such that the cross-sectional area of the first portion 231A of the first inner portion 231 in its extension direction is larger than the cross-sectional area of the first outer portion 232 in its extension direction. Likewise, the cross-sectional area of the second portion 231B of the first inner portion 231 in its extension direction is larger than the cross-sectional area of the first outer portion 232 in its extension direction.

As explained below, the semiconductor device A30 may have, without limitation, the following advantages.

The semiconductor device A30 comprises the first die pad 21, the first suspension lead 23, the second suspension lead 24, the first semiconductor element 11, and the sealing resin 50. The first suspension lead 23 includes the first inner portion 231 covered by the sealing resin 50 and the first outer portion 232 connected to the first inner portion 231 and exposed to the outside. As viewed in the third direction z, the first inner portion 231 includes the first portion 231A extending from the boundary defined by the extension line EL of the first edge 21B of the first die pad 21 to the first die pad 21. The cross-sectional area of the first portion 231A in its extension direction is larger than the cross-sectional area of the first outer portion 232 in its extension direction. With this configuration, it is possible to stabilize the position of the die pad in manufacturing the semiconductor device A30. Further, as having the same configurations as those of the semiconductor device A10, the semiconductor device A30 can have the same advantages as the semiconductor device A10.

The semiconductor device A30 further comprises the support lead 28. The support lead 28 is connected to the first die pad 21 and is exposed to the outside from the second side face 54 of the sealing resin 50. With this configuration, as a load acts on the first die pad 21 in the third direction z, the support lead 28, together with the first suspension lead 23, resists the bending in the third direction z. Thus, the deflection of the first suspension lead 23 in the third direction z is further reduced as is possible with the semiconductor device A10, thereby further stabilizing the position of the first die pad 21.

The present disclosure is not limited to the embodiments described above. The specific configurations of each part disclosed herein may be modified in various ways.

The present disclosure includes the embodiments presented in the following clauses.

### Clause 1

A semiconductor device comprising:
a first die pad;
a first suspension lead connected to one side of the first die pad in a first direction;
a second suspension lead opposite from the first suspension lead with respect to the first die pad and connected to the first die pad;
a first semiconductor element mounted on the first die pad; and
a sealing resin covering the first die pad and the first semiconductor element,
wherein the sealing resin includes two first side faces facing away from each other in the first direction, and a second side face facing in a second direction perpendicular to the first direction,
each of the first suspension lead and the second suspension lead is spaced apart from the two first side faces and exposed to an outside from the second side face,
the first suspension lead includes a first inner portion covered by the sealing resin and a first outer portion connected to the first inner portion and exposed to the outside,
the first die pad includes a first edge extending in the first direction and disposed closest to the second side face,
as viewed in a third direction perpendicular to the first direction and the second direction, the first inner portion includes a first portion extending from a boundary defined by an extension of the first edge to the first die pad,
a cross-sectional area of the first portion in a direction in which the first portion extends is larger than a cross-sectional area of the first outer portion in a direction in which the first outer portion extends.

### Clause 2

The semiconductor device according to clause 1, wherein the first inner portion includes a second portion that connects the first portion and the first outer portion to each other,
a cross-sectional area of the second portion in a direction in which the second portion extends is larger than the cross-sectional area of the first outer portion in the direction in which the first outer portion extends.

### Clause 3

The semiconductor device according to clause 2, wherein the second suspension lead includes a second inner portion covered by the sealing resin and a second outer portion connected to the second inner portion and exposed to the outside,
a cross-sectional area of the second inner portion in a direction in which the second inner portion extends is larger than a cross-sectional area of the second outer portion in a direction in which the second outer portion extends.

### Clause 4

The semiconductor device according to clause 3, wherein each of the first outer portion and the second outer portion extends in the second direction.

### Clause 5

The semiconductor device according to clause 4, wherein the first outer portion is formed with a cutting mark facing in the first direction,
the first outer portion includes a third portion disposed between the second side face and the cutting mark, and a fourth portion opposite from the third portion with respect to the cutting mark,
a cross-sectional area of the third portion in a direction in which the third portion extends is larger than a cross-sectional area of the fourth portion in a direction in which the fourth portion extends.

### Clause 6

The semiconductor device according to any one of clauses 3-5, further comprising:
a second die pad spaced apart from the first die pad in the second direction; and
a second semiconductor element mounted on the second die pad,
wherein the second die pad and the second semiconductor element are covered by the sealing resin.

### Clause 7

The semiconductor device according to clause 6, further comprising:
a third suspension lead disposed on a same side as the first suspension lead with respect to the first die pad in the first direction and connected to the second die pad; and
a fourth suspension lead opposite from the third suspension lead with respect to the second die pad and connected to the second die pad,
wherein the sealing resin includes a third side face facing away from the second side face in the second direction,
each of the third suspension lead and the fourth suspension lead is spaced apart from the two first side face and exposed to the outside from the third side face.

### Clause 8

The semiconductor device according to clause 7, wherein the third suspension lead includes a third inner portion covered by the sealing resin and a third outer portion connected to the third inner portion and exposed to the outside,
a cross-sectional area of the third inner portion in a direction in which the third inner portion extends is larger than a cross-sectional area of the third outer portion in a direction in which the third outer portion extends.

### Clause 9

The semiconductor device according to clause 8, wherein the first die pad is greater in area than the second die pad as viewed in the third direction.

### Clause 10

The semiconductor device according to clause 9, further comprising an insulating element mounted on the first die pad, wherein the insulating element is of inductive coupling type,
the insulating element is electrically connected to the first semiconductor element and the second semiconductor element.

### Clause 11

The semiconductor device according to clause 10, wherein the insulating element is next to the first semiconductor element in the second direction,
the first die pad is formed with two first holes and a second hole that each extend through the first die pad in the third direction,
the two first holes are on respective sides of the first semiconductor element in the first direction,
the second hole is disposed between the first semiconductor element and the insulating element in the second direction.

### Clause 12

The semiconductor device according to clause 11, wherein the second hole extends in the first direction.

### Clause 13

The semiconductor device according to clause 12, wherein the first inner portion, the second inner portion and the second hole are disposed to overlap with a virtual line extending in the first direction as viewed in the third direction.

### Clause 14

The semiconductor device according to clause 13, wherein the first inner portion and the second inner portion are disposed to overlap with the first die pad as viewed in the first direction.

### Clause 15

The semiconductor device according to clause 14, wherein the third inner portion is disposed to overlap with the second die pad as viewed in the first direction.

### Clause 16

The semiconductor device according to clause 15, further comprising first intermediate leads disposed between the first suspension lead and the second suspension lead, wherein at least one of the first intermediate leads is electrically connected to the first semiconductor element.

### Clause 17

The semiconductor device according to clause 16, further comprising second intermediate leads disposed between the third suspension lead and the fourth suspension lead, wherein at least one of the second intermediate leads is electrically connected to the second semiconductor element.

### REFERENCE NUMERALS

A10, A20, A30: Semiconductor device
11: First semiconductor element
111: First electrode
12: Second semiconductor element
121: Second electrode
13: Insulating element
131: Third electrode
132: Fourth electrode
21: First die pad
21A: First mounting surface
21B: First edge
211: First hole
212: Second hole
213: Third hole
22: Second die pad
22A: Second mounting surface
23: First suspension lead
231: First inner portion
231A: First portion
231B: Second portion
232: First outer portion
232A: Cutting mark
232B: Third portion
232C: Fourth portion
24: Second suspension lead
241: Second inner portion
242: Second outer portion
25: Third suspension lead
251: Third inner portion
252: Third outer portion
26: Fourth suspension lead
261: Fourth inner portion
262: Fourth outer portion
27: Outer lead
271: Inner portion
272: Outer portion
28: Support lead
28A: End face
29: Bonding layer
31: First intermediate lead
311: Inner portion
312: Outer portion
32: Second intermediate lead
321: Inner portion
322: Outer portion
41: First wire
42: Second wire
43: Third wire
44: Fourth wire
50: Sealing resin
51: Top face
52: Bottom face
53: First side face
531: First upper portion
532: First lower portion
533: First intermediate portion
54: Second side face
541: Second upper portion
542: Second lower portion
543: Second intermediate portion
55: Third side face
551: Third upper portion
552: Third lower portion
553: Third intermediate portion
80: Lead frame
81: Frame portion
82: Tie bar
x: First direction
y: Second direction
z: Third direction

1. A semiconductor device comprising:
a first die pad;
a first suspension lead connected to one side of the first die pad in a first direction;
a second suspension lead opposite from the first suspension lead with respect to the first die pad and connected to the first die pad;
a first semiconductor element mounted on the first die pad; and
a sealing resin covering the first die pad and the first semiconductor element,
wherein the sealing resin includes two first side faces facing away from each other in the first direction, and a second side face facing in a second direction perpendicular to the first direction,
each of the first suspension lead and the second suspension lead is spaced apart from the two first side faces and exposed to an outside from the second side face,
the first suspension lead includes a first inner portion covered by the sealing resin and a first outer portion connected to the first inner portion and exposed to the outside,
the first die pad includes a first edge extending in the first direction and disposed closest to the second side face,
as viewed in a third direction perpendicular to the first direction and the second direction, the first inner portion includes a first portion extending from a boundary defined by an extension of the first edge to the first die pad,
a cross-sectional area of the first portion in a direction in which the first portion extends is larger than a cross-sectional area of the first outer portion in a direction in which the first outer portion extends.

2. The semiconductor device according to claim 1, wherein the first inner portion includes a second portion that connects the first portion and the first outer portion to each other,
a cross-sectional area of the second portion in a direction in which the second portion extends is larger than the cross-sectional area of the first outer portion in the direction in which the first outer portion extends.

3. The semiconductor device according to claim 2, wherein the second suspension lead includes a second inner portion covered by the sealing resin and a second outer portion connected to the second inner portion and exposed to the outside,
a cross-sectional area of the second inner portion in a direction in which the second inner portion extends is larger than a cross-sectional area of the second outer portion in a direction in which the second outer portion extends.

4. The semiconductor device according to claim 3, wherein each of the first outer portion and the second outer portion extends in the second direction.

5. The semiconductor device according to claim 4, wherein the first outer portion is formed with a cutting mark facing in the first direction,
the first outer portion includes a third portion disposed between the second side face and the cutting mark, and a fourth portion opposite from the third portion with respect to the cutting mark,
a cross-sectional area of the third portion in a direction in which the third portion extends is larger than a cross-sectional area of the fourth portion in a direction in which the fourth portion extends.

6. The semiconductor device according to claim 3, further comprising:
a second die pad spaced apart from the first die pad in the second direction; and
a second semiconductor element mounted on the second die pad,
wherein the second die pad and the second semiconductor element are covered by the sealing resin.

7. The semiconductor device according to claim 6, further comprising:
a third suspension lead disposed on a same side as the first suspension lead with respect to the first die pad in the first direction and connected to the second die pad; and
a fourth suspension lead opposite from the third suspension lead with respect to the second die pad and connected to the second die pad,
wherein the sealing resin includes a third side face facing away from the second side face in the second direction,
each of the third suspension lead and the fourth suspension lead is spaced apart from the two first side face and exposed to the outside from the third side face.

8. The semiconductor device according to claim 7, wherein the third suspension lead includes a third inner portion covered by the sealing resin and a third outer portion connected to the third inner portion and exposed to the outside,
a cross-sectional area of the third inner portion in a direction in which the third inner portion extends is larger than a cross-sectional area of the third outer portion in a direction in which the third outer portion extends.

9. The semiconductor device according to claim 8, wherein the first die pad is greater in area than the second die pad as viewed in the third direction.

10. The semiconductor device according to claim 9, further comprising an insulating element mounted on the first die pad, wherein the insulating element is of inductive coupling type,
the insulating element is electrically connected to the first semiconductor element and the second semiconductor element.

11. The semiconductor device according to claim 10, wherein the insulating element is next to the first semiconductor element in the second direction,
the first die pad is formed with two first holes and a second hole that each extend through the first die pad in the third direction,
the two first holes are on respective sides of the first semiconductor element in the first direction,
the second hole is disposed between the first semiconductor element and the insulating element in the second direction.

12. The semiconductor device according to claim 11, wherein the second hole extends in the first direction.

13. The semiconductor device according to claim 12, wherein the first inner portion, the second inner portion and the second hole are disposed to overlap with a virtual line extending in the first direction as viewed in the third direction.

14. The semiconductor device according to claim 13, wherein the first inner portion and the second inner portion are disposed to overlap with the first die pad as viewed in the first direction.

15. The semiconductor device according to claim 14, wherein the third inner portion is disposed to overlap with the second die pad as viewed in the first direction.

16. The semiconductor device according to claim 15, further comprising first intermediate leads disposed between the first suspension lead and the second suspension lead, wherein at least one of the first intermediate leads is electrically connected to the first semiconductor element.

17. The semiconductor device according to claim 16, further comprising second intermediate leads disposed between the third suspension lead and the fourth suspension lead, wherein at least one of the second intermediate leads is electrically connected to the second semiconductor element.
